(19) United States
(12) Patent Application Publication
(10) Pub. No.: US 2024/0319577 A1
(43) Pub. Date: Sep. 26, 2024

(54) REFLECTIVE MASK BLANK, REFLECTIVE MASK, AND METHOD OF MANUFACTURING REFLECTIVE MASK

(71) Applicant: HOYA CORPORATION, Tokyo (JP)

(72) Inventors: Hitoshi MAEDA, Tokyo (JP); Yohei IKEBE, Tokyo (JP)

(73) Assignee: HOYA CORPORATION, Tokyo (JP)

(21) Appl. No.: 18/592,926

(22) Filed: Mar. 1, 2024

(30) Foreign Application Priority Data
Mar. 22, 2023 (JP) 2023-045077

(51) Int. Cl. G03F 1/24

(52) U.S. Cl. CPC G03F 1/24

(57) ABSTRACT

A reflective mask blank comprises a substrate, a multilayer reflective film formed on the substrate, and a thin film formed on the multilayer reflective film. The thin film includes a first layer and a second layer. The first layer has a reflectance greater than 2.5% with respect to EUV light. The second layer has a reflectance greater than the reflectance of the first layer with respect to the EUV light.

### CROSS-REFERENCE TO RELATED APPLICATION

This application claims priority to Japanese Patent Application No. 2023-045077 filed Mar. 22, 2023, the content of which is incorporated herein by reference in its entirety.

### TECHNICAL FIELD

The present disclosure relates to a reflective mask blank, a reflective mask, and a method of manufacturing a reflective mask.

### BACKGROUND ART

In semiconductor devices, the finer a pattern such as a wiring pattern is and the higher an accuracy in pattern dimension and pattern position is, the more electrical characteristics and performance as well as a degree of integration are improved and the smaller a chip size is. In view of the above, EUV lithography using extreme ultraviolet (EUV) having a wavelength around 13.5 nm has been developed. For the EUV lithography, there is a demand for higher-accuracy transfer performance in transferring a fine-dimension pattern.

In the EUV lithography, a reflective mask is used because there are few materials transparent to EUV light. When the reflective mask is a phase shift reflective mask having a phase shift effect, it is expected to improve a contrast in a transfer pattern and to thereby improve a resolution. Therefore, in order to transfer the fine-dimension pattern with a high accuracy, it is effective to use the phase shift reflective mask as described in JP 2010-080659 A and JP 2004-207593 A.

In exposure using the phase shift reflective mask, a reflectance for obtaining an excellent phase shift effect may be different depending on a type of a pattern to be transferred. Depending on the type (shape), a pitch, and so on of the pattern, a high reflectance or a low reflectance may be preferred. However, in a high-reflectance portion, a high phase shift effect can be obtained while an exposure margin is reduced. This causes a risk that a resist on a transfer-target (semiconductor) substrate reacts to light in a region where the resist should not react to light. On the other hand, in a low-reflectance portion, the exposure margin is increased while the phase shift effect is reduced.

Therefore, in order to form a pattern region preferably having a relatively high reflectance and a pattern region preferably having a relatively low reflectance on the transfer-target substrate by using existing phase shift masks, two or more phase shift masks are required. Furthermore, how to set the pattern region having the relatively high reflectance and the pattern region having the relatively low reflectance depends on a transfer-target semiconductor device. Therefore, a mask blank preferably has a high degree of freedom in design so that a region having a desired reflectance can be set corresponding to a type of a pattern to be formed on a transfer target.

### SUMMARY OF THE DISCLOSURE

It is therefore an aspect of the present disclosure to provide a reflective mask which enables transferring of a fine pattern with a high accuracy by achieving both a high phase shift effect and a large exposure margin.

It is another aspect of the present disclosure to provide a reflective mask blank from which the above-mentioned reflective mask can be manufactured.

It is still another aspect of the present disclosure to provide a method of manufacturing a reflective mask, which is capable of simultaneously achieving a high phase shift effect and a large exposure margin with one reflective mask.

It is a further aspect of the present disclosure to provide a method of manufacturing a semiconductor device, which is capable of achieving high performance and a high degree of integration by using the above-mentioned reflective mask.

In order to achieve the above-mentioned aspects, the present disclosure has the following configurations.

### Configuration 1

A reflective mask blank comprising:
a substrate;
a multilayer reflective film formed on the substrate; and
a thin film formed on the multilayer reflective film;
wherein the thin film includes a first layer and a second layer;
wherein the first layer has a reflectance greater than 2.5% with respect to EUV light; and
wherein the second layer has a reflectance greater than the reflectance of the first layer with respect to the EUV light.

### Configuration 2

The reflective mask blank according to Configuration 1,
wherein a phase difference between first reflected light reflected from the first layer irradiated with the EUV light and second reflected light reflected from the second layer irradiated with the EUV light is 30 degrees or less.

### Configuration 3

The reflective mask blank according to Configuration 1,
wherein light reflected from the multilayer reflective film irradiated with the EUV light is defined as reference reflected light;
wherein a phase difference between the reference reflected light and first reflected light reflected from the first layer irradiated with the EUV light is 150 degrees or more;
wherein a phase difference between the reference reflected light and second reflected light reflected from the second layer irradiated with the EUV light is 150 degrees or more.

### Configuration 4

The reflective mask blank according to Configuration 1,
wherein the thin film has a lowermost layer formed closest to the substrate.

### Configuration 5

The reflective mask blank according to Configuration 1,
wherein the first layer or the second layer comprises at least one of ruthenium, tantalum, and chromium.

### Configuration 6

The reflective mask blank according to Configuration 1,
wherein the first layer is formed on the second layer.

### Configuration 7

The reflective mask blank according to Configuration 6,
wherein the second layer comprises at least one of ruthenium and chromium.

### Configuration 8

The reflective mask blank according to Configuration 1,
wherein an etching mask film that comprises two or more layers is formed on the thin film.

### Configuration 9

A method of manufacturing a reflective mask using the reflective mask blank comprising:
forming an etching mask pattern by etching the etching mask film;
forming a first upper layer pattern by etching the upper layer with the etching mask pattern used as a mask;
forming a lower layer pattern by etching the lower layer with the first upper layer pattern used as a mask; and
forming a transfer pattern by etching the first upper layer pattern to form a second upper layer pattern,
wherein one of the first layer and the second layer which is formed closer to the substrate is defined as a lower layer and the other is defined as an upper layer, and
wherein the first layer has a reflectance greater than 2.5% with respect to EUV light, and
wherein the second layer has a reflectance greater than the reflectance of the first layer with respect to the EUV light.

### Configuration 10

The method of manufacturing a reflective mask according to Configuration 9,
wherein the thin film has a lowermost layer formed under the lower layer;
wherein the method further comprises removing the lowermost layer in a region where the lower layer has been etched.

### Configuration 11

A reflective mask comprising
a substrate;
a multilayer reflective film formed on the substrate; and
a thin film formed on the multilayer reflective film and provided with a transfer pattern;
wherein the thin film includes a first layer and a second layer;
wherein the first layer has a reflectance greater than 2.5% with respect to EUV light;
wherein the second layer has a reflectance greater than the reflectance of the first layer with respect to the EUV light.

### Configuration 12

The reflective mask according to Configuration 11,
wherein a phase difference between first reflected light reflected from the first layer irradiated with the EUV light and second reflected light reflected from the second layer irradiated with the EUV light is 30 degrees or less.

### Configuration 13

The reflective mask according to Configuration 11,
wherein light reflected from the multilayer reflective film irradiated with the EUV light is defined as reference reflected light;
wherein a phase difference between the reference reflected light and first reflected light reflected from the first layer irradiated with the EUV light is 150 degrees or more;
wherein a phase difference between the reference reflected light and second reflected light reflected from the second layer irradiated with the EUV light is 150 degrees or more.

### Configuration 14

The reflective mask according to Configuration 11,
wherein the thin film has a lowermost layer formed closest to the substrate.

### Configuration 15

The reflective mask according to Configuration 11,
wherein the first layer or the second layer comprises at least one of ruthenium, tantalum, and chromium.

### Configuration 16

The reflective mask according to Configuration 11,
wherein the first layer is formed on the second layer.

### Configuration 17

The reflective mask according to Configuration 16, wherein the second layer comprises at least one of ruthenium and chromium.

### Configuration 18

The reflective mask according to Configuration 11, wherein each of the first layer and the second layer is at least partially exposed in plan view.

### Configuration 19

The reflective mask according to Configuration 11,
wherein the reflective mask has a stacked region in which at least a part of the second layer is covered with the first layer;
wherein the second layer is exposed at an outer periphery of the stacked region.

### Configuration 20

The method according to Configuration 9,
wherein a phase difference between first reflected light reflected from the first layer irradiated with the EUV light and second reflected light reflected from the second layer irradiated with the EUV light is 30 degrees or less.

### Configuration 21

The method according to Configuration 9,
wherein light reflected from the multilayer reflective film irradiated with the EUV light is defined as reference reflected light;
wherein a phase difference between the reference reflected light and first reflected light reflected from the first layer irradiated with the EUV light is 150 degrees or more;
wherein a phase difference between the reference reflected light and second reflected light reflected from the second layer irradiated with the EUV light is 150 degrees or more.

According to the present disclosure, it is possible to provide a reflective mask which enables transferring of a fine pattern with a high accuracy by achieving both a high phase shift effect and a large exposure margin, to provide a reflective mask blank from which the above-mentioned reflective mask can be manufactured, to provide a method of manufacturing a reflective mask, which is capable of simultaneously achieving a high phase shift effect and a large exposure margin with one reflective mask, and to provide a method of manufacturing a semiconductor device, which is capable of achieving high performance and a high degree of integration by using the above-mentioned reflective mask.

### BRIEF DESCRIPTION OF THE DRAWINGS

FIG. 1 is a cross-sectional view showing a configuration of a reflective mask blank according to an embodiment of the present disclosure;

FIG. 2 is a cross-sectional view showing a configuration of a reflective mask according to an embodiment of the present disclosure;

FIG. 3 is a plan view showing the configuration of the reflective mask according to the embodiment of the present disclosure;

FIG. 4 is a cross-sectional view showing a reflective mask having another configuration according to the embodiment of the present disclosure;

FIGS. 5A to 5G are cross-sectional views for describing an example of a method of manufacturing a reflective mask according to an embodiment of the present disclosure; and

FIG. 6 is a view showing compositions and physical properties of thin films in Examples and Comparative Example.

### DETAILED DESCRIPTION OF THE DISCLOSURE

In the present specification, a reflectance (an absolute reflectance and a relative reflectance) represents a value in a case where an incident angle of EUV light to a thin film 40 (a first layer 41 and a second layer 42) or a multilayer reflective film 20 (including a protective film 30, this applies also in the following) is the same as an incident angle of EUV light to an irradiated object such as a thin film having a transfer pattern when the EUV light is used in exposure upon pattern transfer using a reflective mask 1a or 1a′ or a reflective mask 1a or 1a′ manufactured from a reflective mask blank 1. The EUV light of an EUV light source during the pattern transfer is emitted via an illumination optical system to the reflective mask 1a or 1a′ at an inclination angle of, for example, 6 to 8 degrees with respect to a plane perpendicular to a main surface of the reflective mask 1a or 1a′. The incident angle of the EUV light to the thin film 40 or the multilayer reflective film 20 is not particularly limited but may be, for example, 6 degrees.

### <<Reflective Mask Blank and Reflective Mask>>

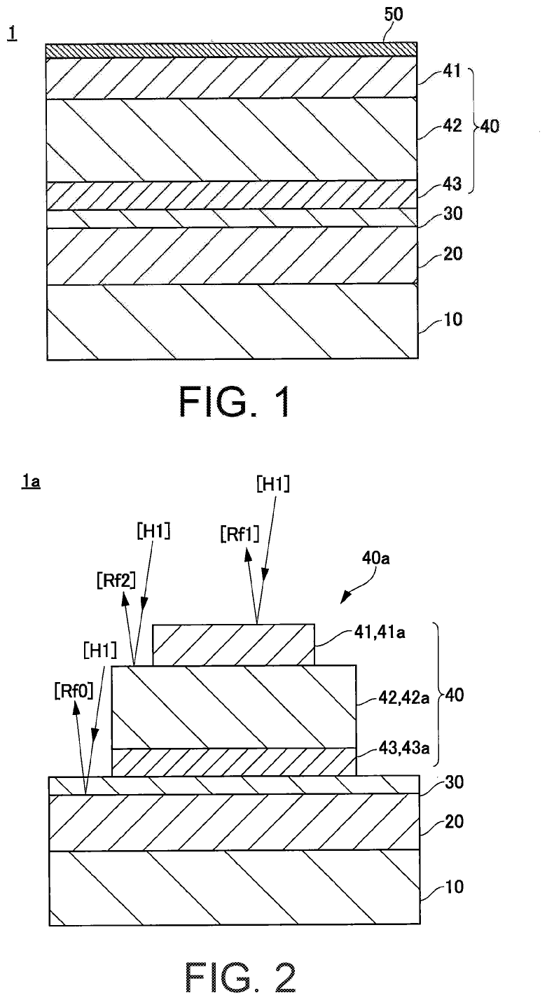

FIG. 1 is a cross-sectional view showing a configuration of the reflective mask blank 1 according to an embodiment of the present disclosure. The reflective mask blank 1 shown in the figure is an original plate of a reflective mask for EUV lithography using extreme ultraviolet (EUV) as exposure light. The EUV light (EUV radiation) is light (electromagnetic waves) including light having a wavelength of 13.5 nm, and may be light having a wavelength of 13 nm to 14 nm, more specifically, light having a wavelength of 13.5 nm. Herein, the light includes not only visible light but also electromagnetic waves. FIG. 2 is a cross-sectional view showing a configuration of the reflective mask 1a according to an embodiment of the present disclosure. The reflective mask 1a is manufactured by processing the reflective mask blank 1 shown in FIG. 1. The reflective mask 1a is for use in the EUV lithography, and is a phase shift mask.

The reflective mask blank 1 shown in FIG. 1 includes a substrate 10 and the multilayer reflective film 20, the protective film 30, and the thin film 40 stacked on one main surface (first main surface) of the substrate 10 in this order from a side adjacent to the substrate 10. The thin film 40 is a film on which a transfer pattern is to be formed by processing. The reflective mask blank 1 may have an etching mask film 50 formed on the thin film 40 as needed. The reflective mask blank 1 may include a resist film formed on the etching mask film 50 as needed. The etching mask film 50 and the resist film are removed in a manufacturing process of the reflective mask 1a.

The reflective mask 1a shown in FIG. 2 has a transfer pattern 40a formed by patterning the thin film 40 of the reflective mask blank 1 shown in FIG. 1. Hereinafter, details of each part constituting the reflective mask blank 1 and the reflective mask 1a will be described with reference to FIGS. 1 and 2.

### <Substrate 10>

The substrate 10 is preferably made of a material having a low coefficient of thermal expansion within a range of 0±5 ppb/° C. in order to prevent distortion of the transfer pattern 40a due to heat generation during exposure by the EUV light [H1] (EUV exposure) using the reflective mask 1a. For example, SiO₂—TiO₂ based glass, multi-component glass ceramics, and the like may be used as the material. The transfer pattern 40a is a pattern formed by processing the thin film 40 as described above.

In the substrate 10, a back surface without the thin film 40 is a surface to be electrostatically chucked when the reflective mask 1a is set in an exposure device, and is provided with a conductive film (not shown). The back surface refers to the other main surface opposite to the first main surface provided with the thin film 40.

The first main surface of the substrate 10 on which the transfer pattern 40a is to be formed is surface-treated to have a high flatness from the viewpoint of obtaining at least a pattern transfer accuracy and a positional accuracy. In the case of the EUV exposure, the first main surface of the substrate 10 preferably has a flatness of 0.1 μm or less, more preferably 0.05 μm or less, particularly preferably 0.03 μm or less in a region of 132 mm×132 mm. The back surface of the substrate 10 preferably has a flatness of 0.1 μm or less, more preferably 0.05 μm or less, particularly preferably 0.03 μm or less in a region of 132 mm×132 mm. A back surface of the reflective mask blank 1 preferably has a flatness of 1 μm or less, more preferably 0.5 μm or less, particularly preferably 0.3 μm or less in a region of 142 mm×142 mm. It should be noted that, in the present specification, the flatness is a value representing a warpage (deformation amount) of a surface indicated by TIR (Total Indicated Reading). This value is an absolute value of a height difference between a highest position of the surface of the substrate 10 above a focal plane and a lowest position of the surface of the substrate 10 below the focal plane where the focal plane is a plane defined by a least square method with respect to the surface of the substrate 10 as a reference.

Also, the substrate 10 preferably has a high surface roughness. The first main surface on which the transfer pattern 40a is to be formed preferably has a surface roughness of 0.1 nm or less in root mean square roughness (RMS). The surface roughness can be measured by an atomic force microscope.

Furthermore, the substrate 10 preferably has a high rigidity in order to prevent the film (such as the multilayer reflective film 20) formed thereon from being deformed due to film stress. In particular, the substrate 10 preferably has a high Young's modulus of 65 GPa or more.

### <Multilayer Reflective Film 20>

The multilayer reflective film 20 is formed on the first main surface of the substrate 10 and reflects the EUV light [H1] as the exposure light at a high reflectance. In the reflective mask 1a formed by using the reflective mask blank 1, the multilayer reflective film 20 reflects the EUV light [H1] and is a multilayer film formed by periodically stacking different kinds of layers mainly composed of substances different in refractive index, respectively. The multilayer reflective film 20 may further include the protective film 30 on a surface layer which will later be described. In this case, reflected light reflected from the multilayer reflective film 20 refers to light reflected from the multilayer reflective film 20, the light having been incident to the multilayer reflective film 20 via the protective film 30. That is, when the reflective mask blank 1 or the reflective mask 1a includes the protective film 30, the reflected light from a surface of the protective film 30 which is formed on the multilayer reflective film 20 on the substrate 10 is measured as the reflected light reflected from the multilayer reflective film 20.

In general, a multilayer film in which thin films (high refractive index layers) of a light element as a high refractive index material or a compound thereof, and thin films (low refractive index layers) of a heavy element as a low refractive index material or a compound thereof, are alternately stacked in about 30 to 60 periods (sets) is used as the multilayer reflective film 20.

In order to form the multilayer reflective film 20, a plurality of periods (sets) of the high refractive index layers and the low refractive index layers may be stacked in this order on the substrate 10. In this case, one period (set) includes a stacked structure of one high refractive index layer and one low refractive index layer. Alternatively, in order to form the multilayer reflective film 20, a plurality of periods of the low refractive index layers and the high refractive index layers may be stacked in this order on the substrate 10. In this case, one period includes a stacked structure of one low refractive index layer and one high refractive index layer.

Preferably, an uppermost layer of the multilayer reflective film 20, that is, a surface layer of the multilayer reflective film 20 on the side that faces away from the substrate 10, is a high refractive index layer. When the high refractive index layer and the low refractive index layer are stacked in this order on the substrate 10, the uppermost layer is the low refractive index layer. However, when the low refractive index layer is a surface of the multilayer reflective film 20, the low refractive index layer may easily be oxidized to reduce the reflectance of the surface of the multilayer reflective film 20. Therefore, it is preferable to form another high refractive index layer on the low refractive index layer. On the other hand, when the low refractive index layer and the high refractive index layer are stacked in this order on the substrate 10, the uppermost layer is the high refractive index layer. In this case, the high refractive index layer as the uppermost layer is the surface of the multilayer reflective film 20.

In this embodiment, a layer containing silicon (Si) is used as the high refractive index layer. As a material containing Si, elemental Si or a Si compound containing Si and at least one of boron (B), carbon (C), nitrogen (N), and oxygen (O) may be used. By using the layer containing Si as the high refractive index layer for the multilayer reflective film 20, the reflective mask 1a for the EUV lithography, having excellent reflectance with respect to the EUV light [H1], is obtained. Furthermore, in the present embodiment, a glass substrate is preferably used as the substrate 10. Si is excellent also in adhesion to the glass substrate and is therefore preferable as a material constituting the high refractive index layer.

As the low refractive index layer, an elemental metal selected from molybdenum (Mo), ruthenium (Ru), rhodium (Rh), and platinum (Pt), or an alloy thereof, is used. For example, as the multilayer reflective film 20 for the EUV light [H1] having a wavelength of 13 nm to 14 nm, a Mo/Si periodically stacked film, in which Mo films and Si films are alternately stacked in about 30 to 60 periods (sets), is preferably used.

In addition, the multilayer reflective film 20 used in the region of the EUV light [H1] may be, for example, a Ru/Si periodic multilayer film, a Mo/Be (beryllium) periodic multilayer film, a Mo-compound/Si-compound periodic multilayer film, a Si/Nb (niobium) periodic multilayer film, a Si/Mo/Ru periodic multilayer film, a Si/Mo/Ru/Mo periodic multilayer film, a Si/Ru/Mo/Ru periodic multilayer film or the like. The material of the multilayer reflective film 20 may be selected taking an exposure wavelength into consideration.

Preferably, the reflectance of the multilayer reflective film 20 is 65% or more, for example. Preferably, an upper limit of the reflectance of the multilayer reflective film 20 is 73%, for example. Thicknesses of the respective layers of the multilayer reflective film 20 and the number of periods may be selected so as to satisfy the Bragg's law. Herein, the reflectance of the multilayer reflective film 20 means the reflectance from the surface of the multilayer reflective film 20 when the multilayer reflective film 20 is formed on the substrate 10. When the multilayer reflective film 20 includes the protective film 30, the reflectance of the multilayer reflective film 20 means the reflectance from the protective film 30 which is formed on the multilayer reflective film 20 on the substrate 10.

The multilayer reflective film 20 may be formed by known methods. The multilayer reflective film 20 may be formed by, for example, ion beam sputtering.

For example, when the multilayer reflective film 20 is a Mo/Si multilayer film, a Si film having a thickness of about 4 nm is formed on the substrate 10 by ion beam sputtering using a Si target. Then, using a Mo target, a Mo film having a thickness of about 3 nm is formed. By repeating such operation, the multilayer reflective film 20 in which the Mo/Si films are stacked in 30 to 60 periods (sets) can be formed. At this time, the surface layer of the multilayer reflective film 20 on the side that faces away from the substrate 10 is preferably a Si-containing layer (Si film). One period (set) of the Mo/Si films has a thickness of 7 nm.

### <Protective Film 30>

The protective film 30 is a film to protect the surface layer of the multilayer reflective film 20 and a lower layer under the surface layer from etching and cleaning when the reflective mask blank 1 is processed to manufacture the reflective mask 1a for the EUV lithography. The protective film 30 is formed on the surface layer of the multilayer reflective film 20 in contact with the surface layer or with another film interposed therebetween. In the reflective mask 1a, the protective film 30 may also serve to protect the multilayer reflective film 20 when black defects in the transfer pattern 40a are repaired using an electron beam (EB).

Although FIGS. 1 and 2 show a case where the protective film 30 consists of one layer, the protective film 30 may have a stacked structure of two or more layers. The protective film 30 is formed of a material resistant to an etchant for use in patterning the thin film 40 and to a cleaning liquid. By forming the protective film 30 on the multilayer reflective film 20, it is possible to suppress a damage to the surface of the multilayer reflective film 20 when the reflective mask 1a is manufactured using the substrate 10 having the multilayer reflective film 20 and the protective film 30. Therefore, reflectance characteristics of the multilayer reflective film 20 with respect to the EUV light [H1] become excellent. In the following, the case where the protective film 30 consists of one layer will be described by way of example.

In the reflective mask blank 1 of the present embodiment, a material resistant to an etching gas used in dry etching for patterning the thin film 40 formed on the protective film 30 may be selected as a material of the protective film 30. A thickness of the protective film 30 is not particularly limited as long as the protective film 30 can protect the surface layer and the lower layer of the multilayer reflective film 20. Preferably, however, the thickness of the protective film 30 is 1 nm or more and 20 nm or less. In view of the reflectance with respect to the EUV light, the thickness of the protective film 30 is preferably 1.0 nm to 8.0 nm, more preferably 1.5 nm to 6.0 nm.

When the thin film 40 is formed by stacking a plurality of layers, a material resistant to an etching gas for patterning a lowermost layer of the thin film 40 is used as the material of the protective film 30. When the protective film 30 is formed by stacking a plurality of layers, the material resistant to the etching gas for patterning the lowermost layer of the thin film 40 is used as the material of an uppermost layer of the protective film 30.

Preferably, the material of the protective film 30 is a material such that an etching selectivity ratio of the lowermost layer of the thin film 40 to the protective film 30 (etching rate of the lowermost layer of the thin film 40/etching rate of the protective film 30) is 1.5 or more, preferably 3 or more.

For example, when the lowermost layer of the thin film 40 is made of a material (predetermined Ru-based material) containing a metal including ruthenium (Ru) and at least one element selected from chromium (Cr), nickel (Ni) and cobalt (Co), or a material (predetermined Ru-based material) containing a metal including ruthenium (Ru) and at least one element selected from vanadium (V), niobium (Nb), molybdenum (Mo), tungsten (W), and rhenium (Re), the lowermost layer of the thin film 40 can be etched by a dry etching gas using a gas mixture of a chlorine-based gas and oxygen gas or using oxygen gas. As the material of the protective film 30 resistant against the dry etching gas, a silicon-based material, such as an elemental silicon (Si), a material containing silicon (Si) and oxygen (O) and/or nitrogen (N), may be selected. Therefore, when the lowermost layer of the thin film 40 in contact with the surface of the protective film 30 is a thin film made of the predetermined Ru-based material, the protective film 30 is preferably made of the silicon-based material mentioned above. The silicon-based material has a resistance to the dry etching gas using the gas mixture of the chlorine-based gas and the oxygen gas or using the oxygen gas. The more the oxygen content of the silicon-based material is, the greater the resistance is. Thus, the material of the protective film 30 is more preferably silicon oxide (SiOₓ, 1≤x≤2), further preferably silicon oxide with greater x in this range, particularly preferably SiO₂.

When the lowermost layer of the thin film 40 in contact with the surface of the protective film 30 is a thin film made of a material containing tantalum (Ta), the lowermost layer of the thin film 40 can be etched by dry etching using an oxygen-free halogen-based gas. A material containing ruthenium (Ru) as a main component may be used as the material of the protective film 30 resistant to the etching gas mentioned above. Herein, a substance A being contained as the main component means the substance A being contained in an amount of 50 atomic % or more.

When the lowermost layer of the thin film 40 in contact with the surface of the protective film 30 is a thin film made of a material containing chromium (Cr), the lowermost layer of the thin film 40 can be etched by dry etching using a dry etching gas which is an oxygen-free chlorine-based gas or a gas mixture of oxygen gas and a chlorine-based gas. A material containing ruthenium (Ru) as a main component may be used as the material of the protective film 30 resistant to the etching gas mentioned above.

In the case where the lowermost layer of the thin film 40 is made of a material containing tantalum (Ta) or chromium (Cr), the protective film 30 can be made of a material containing ruthenium as a main component, as described above. Examples of the material containing ruthenium as the main component include Ru elemental metal, a Ru alloy containing Ru and at least one metal selected from titanium (Ti), niobium (Nb), molybdenum (Mo), zirconium (Zr), yttrium (Y), boron (B), lanthanum (La), cobalt (Co), chromium (Cr), rhodium (Rh), and rhenium (Re), a material containing a Ru metal and nitrogen, and a material containing a Ru alloy and nitrogen.

An Ru content ratio of the Ru alloy is 50 atomic % or more and less than 100 atomic %, preferably 80 atomic % or more and less than 100 atomic %, more preferably 95 atomic % or more and less than 100 atomic %. In particular, when the Ru content ratio of the Ru alloy is 95 atomic % or more and less than 100 atomic %, it is possible to suppress diffusion of the element (silicon) constituting the multilayer reflective film 20 to the protective film 30. In addition, cleaning resistance of the reflective mask can be improved while ensuring sufficient reflectance with respect to the EUV light. Furthermore, the protective film 30 functions as an etching stopper when the thin film 40 is etched. The protective film 30 can prevent the multilayer reflective film 20 from changing over time.

As the material of the protective film 30, a compound containing Ru, such as a material containing at least one selected from RuNb, RuN, and RuTi, may be used. As the material of the protective film 30, a compound containing Y and O, for example, a material containing Y₂O₃ may be used. As the material of the protective film 30, a compound containing Cr, for example, a material containing CrN may be used.

The material of the protective film 30 may further include at least one selected from oxygen (O), nitrogen (N), carbon (C), and boron (B) in addition to the material described above.

As a method of forming the protective film 30, those similar to known film forming methods may be used without limitation. Specific examples include various sputtering methods, such as DC sputtering, RF sputtering, and ion beam sputtering, and atomic layer deposition (ALD).

<Thin Film 40 and Transfer Pattern 40a>

The thin film 40 is a film used as a phase shift film for the EUV light [H1] and serves as a film for forming the transfer pattern 40a in the reflective mask 1a constructed using the reflective mask blank 1. The transfer pattern 40a is formed by patterning the thin film 40.

In this embodiment, the thin film 40 includes at least the first layer 41 and the second layer 42. Each of the first layer 41 and the second layer 42 functions as a phase shift film for the EUV light [H1]. Each of the first layer 41 and the second layer 42 absorbs the EUV light [H1] and reflects a part of the EUV light [H1] at a level that does not adversely affect the pattern transfer. It should be noted that the thin film 40 may include a film other than the first layer 41 and the second layer 42. For example, the thin film 40 may include a lowermost layer 43 closer to the substrate 10 than the first layer 41 and the second layer 42, and may further include other layers not shown in the figure. Hereinafter, configurations of the first layer 41 and the second layer 42 will be described.

[Reflectance with Respect to EUV Light [H1] (Thin Film 40 and Transfer Pattern 40a)]

Both the first layer 41 and the second layer 42 can be a film which functions as a phase shift film for the EUV light [H1].

Each of an absolute reflectance [R1] of the first layer 41 and an absolute reflectance [R2] of the second layer 42 with respect to the EUV light [H1] is preferably greater than 2.5%, more preferably 3.0% or more. In addition, each of the absolute reflectance [R1] of the first layer 41 and the absolute reflectance [R2] of the second layer 42 with respect to the EUV light is preferably 20% or less, more preferably 15% or less. Consequently, each of the first layer 41 and the second layer 42 may function as the phase shift film.

It is noted that the first layer 41 and the second layer 42 are different in absolute reflectance with respect to the EUV light [H1]. As to the absolute reflectance with respect to the EUV light [H1], the absolute reflectance [R2] of the second layer 42 is higher than the absolute reflectance [R1] of the first layer 41. Thus, the absolute reflectance [R2]>the absolute reflectance [R1].

In the present specification, the absolute reflectance (the reflectance) [R1] of the first layer 41 means the absolute reflectance on a surface of the first layer 41 which is formed on the multilayer reflective film 20 (and the lowermost layer 43) formed on the substrate 10, in the case where the first layer 41 is formed on the multilayer reflective film 20 (and the lowermost layer 43) without the second layer 42 interposed therebetween. In the case where the first layer 41 is formed on the multilayer reflective film 20 with the second layer 42 interposed therebetween, the absolute reflectance [R1] of the first layer 41 means the absolute reflectance on the surface of the first layer 41 which is formed on the second layer 42 formed on the multilayer reflective film 20 (and the lowermost layer 43) on the substrate 10. This applies also to a relative reflectance which will later be described.

The absolute reflectance (the reflectance) [R2] of the second layer 42 means the absolute reflectance on a surface of the second layer 42 which is formed on the multilayer reflective film 20 (and the lowermost layer 43) formed on the substrate 10, in the case where the second layer 42 is formed on the multilayer reflective film 20 (and the lowermost layer 43) without the first layer 41 interposed therebetween. In the case where the second layer 42 is formed on the multilayer reflective film 20 (and the lowermost layer 43) with the first layer 41 interposed therebetween, the absolute reflectance [R2] of the second layer 42 means the absolute reflectance on the surface of the second layer 42 which is formed on the first layer 41 formed on the multilayer reflective film 20 (and the lowermost layer 43) on the substrate 10. This applies also to a relative reflectance which will later be described.

The absolute reflectance refers to an intensity of light (electromagnetic waves) reflected from an irradiated object with respect to an intensity of light incident to the irradiated object. That is, the absolute reflectance of a film or a layer is a value calculated by: (the amount of reflected light from a surface of the film or the layer in question)/(amount of incident light to the surface of the film or the layer in question). When the absolute reflectance is represented by a unit of %, then the above-mentioned value is multiplied by 100. Herein, the reflectance simply referred to means the absolute reflectance unless otherwise noted.

Furthermore, with reference to the reflectance of the multilayer reflective film 20 with respect to the EUV light [H1], the relative reflectance of the first layer 41 with respect to the EUV light is preferably greater than 3%, more preferably 4% or more, further preferably 5% or more, and furthermore preferably 8% or more. This makes it possible to obtain a high phase shift effect. On the other hand, the relative reflectance of the first layer 41 with respect to the EUV light is preferably 40% or less, more preferably 30% or less, further preferably 20% or less. This also applies to the second layer 42. Consequently, it possible to suppress or reduce unnecessary reaction of the resist film to light during pattern transfer. It is noted that the relative reflectance is calculated by: (absolute reflectance of the surface of the film or the layer in question)/(absolute reflectance of the multilayer reflective film 20). When the relative reflectance is represented by a unit of %, then the above-mentioned value is multiplied by 100.

The first layer 41 and the second layer 42 having the respective reflectances as described above are stacked on the one main surface of the substrate 10. However, the order of stacking is not limited. For example, when the second layer 42 is stacked on the first layer 41, the effect when forming a fine pattern can be obtained. It is noted that, by stacking the first layer 41 having a relatively low reflectance with respect to the EUV light [H1] on the second layer 42 having a relatively high reflectance with respect to the EUV light [H1], the effect when forming the fine pattern can be increased as will later be described.

[Phase Difference of Reflected Light (Thin Film 40 and Transfer Pattern 40a)]

A phase difference between first reflected light [Rf1] obtained by reflecting the EUV light [H1] at the first layer 41 and second reflected light [Rf2] obtained by reflecting the EUV light [H1] at the second layer 42 is preferably 30 degrees or less, more preferably 20 degrees or less. In this manner, a better phase shift effect can be obtained.

When the reflected light reflected from the multilayer reflective film 20 irradiated with the EUV light [H1] is defined as reference reflected light [Rf0], a phase difference between the reference reflected light [Rf0] and each of the first reflected light [Rf1] and the second reflected light [Rf2] is 150 degrees or more. When the protective film 30 is formed on the surface layer of the multilayer reflective film 20, the reflected light which is reflected by the multilayer reflective film 20, the multilayer reflective film 20 having been irradiated with the EUV light [H1] through the protective film 30, is referred to as the reference reflected light [Rf0]. The phase difference of the first reflected light [Rf1] with respect to the reference reflected light [Rf0] is preferably 180 degrees or more, more preferably 200 degrees or more, and further preferably 210 degrees or more. The phase difference is preferably 300 degrees or less, more preferably 280 degrees or less, further preferably 250 degrees or less, and furthermore preferably 240 degrees or less. This also applies to the phase difference of the second reflected light [Rf2] with respect to the reference reflected light [Rf0]. With the above-mentioned phase differences, a high phase shift effect can be obtained in exposure using the reflective mask 1a. Herein, a difference between the phase difference of the first reflected light [Rf1] with respect to the reference reflected light [Rf0] and the phase difference of the second reflected light [Rf2] with respect to the reference reflected light [Rf0] is preferably 30 degrees or less, more preferably 20 degrees or less.

[Material (Thin Film 40 and Transfer Pattern 40a)]

The thin film 40 is not limited in material as long as the reflectance and the phase difference of each of the first layer 41 and the second layer 42 with respect to the EUV light [H1] satisfy the above-mentioned conditions. For example, the thin film 40 may be constituted by a material containing at least one of ruthenium (Ru), tantalum (Ta), chromium (Cr), rhodium (Rh), molybdenum (Mo), niobium (Nb), titanium (Ti), zirconium (Zr), yttrium (Y), silicon (Si), palladium (Pd), silver (Ag), platinum (Pt), gold (Au), iridium (Ir), tungsten (W), cobalt (Co), manganese (Mn), tin (Sn), vanadium (V), nickel (Ni), iron (Fe), hafnium (Hf), copper (Cu), tellurium (Te), zinc (Zn), magnesium (Mg), germanium (Ge), and aluminum (Al). In addition, the material may further contain at least one of oxygen (O), nitrogen (N), carbon (C), and boron (B).

Specific examples of the material constituting the thin film 40 include a HfAl material, an AlSi material, a RuN material, a RuCr material, a RuPt material, a RuTa material, a TaNb material, an IrTa material, a Cr material, and a material containing at least one of oxygen (O), nitrogen (N), carbon (C), and boron (B) in addition to the above-mentioned materials. For example, one of the above-mentioned materials may be selected as the first layer 41 whereas another material may be selected as the second layer 42.

Preferably, at least one of the first layer 41 and the second layer 42 is made of a material containing at least one of ruthenium (Ru), tantalum (Ta), and chromium (Cr). Ru has a small refractive index n and a small extinction coefficient k with respect to the EUV light and, therefore, makes it possible to form a film having an excellent phase shift effect and a relatively high reflectance with a small film thickness. Accordingly, it is also possible to reduce a shadowing effect. On the other hand, Ta and Cr have a large extinction coefficient with respect to the EUV light and, therefore, makes it possible to form a phase shift film having a relatively low reflectance. Therefore, unnecessary reaction of the resist film to light can be reduced or suppressed during pattern transfer. In addition, when the extinction coefficient k is large, the film thickness of the phase shift film can be reduced and the shadowing effect can also be reduced. In addition, Ta and Cr have high etching rates for a chlorine-based gas and/or a fluorine-based gas and can easily be dry etched. Thus, using Ta and Cr, it is possible to form a phase shift film excellent in processability. Furthermore, by adding B, Si, Ge, etc., to Ta, an amorphous material can easily be obtained and smoothness of the thin film can be improved. Further, when N or O is added to Ta, it is possible to improve a stability over time an oxidation resistance of the thin film is improved.

Preferably, either the first layer 41 or the second layer is made of a material containing Al. For example, the material containing Al may be the HfAl material or the AlSi material. For example, when the HfAl material is used as either the first layer 41 or the second layer, a ratio Hf/[Hf+Al] of a Hf content (atomic %) to a total content (atomic %) of Hf and Al in the HfAl material is preferably 0.40 or more. This makes it possible to improve resistance of the HfAl material to chemical cleaning. Preferably, Hf/[Hf+Al] is 0.86 or less.

When the AlSi material is used as either the first layer 41 or the second layer, a ratio Si/[Al+Si] of a Si content (atomic %) to a total content (atomic %) of Al and Si in the AlSi material is preferably 0.20 or more from the viewpoint of the resistance to the chemical cleaning. This makes it possible to improve the resistance of the AlSi material to the chemical cleaning. Preferably, Si/[Al+Si] is 0.80 or less.

Preferably, both of the HfAl material and the AlSi material contain oxygen (O). Preferably, both the HfAl material and the AlSi material have an oxygen content of 60 atomic % or more. This makes it possible to improve the stability over time because the oxidation resistance of the thin film of the HfAl material or the AlSi material is improved. An oxygen content of the HfAl material and the AlSi material is preferably 70 atomic % or less, more preferably 66 atomic % or less.

Preferably, the first layer 41 and the second layer 42 of the thin film 40 have etch selectivity with each other. That is, the first layer 41 is preferably resistant to an etchant for etching the second layer 42 and the second layer 42 is preferably resistant to an etchant for etching the first layer 41.

For example, when one of the first layer 41 and the second layer 42 is a layer composed of a material containing ruthenium (Ru) and at least one element selected from chromium (Cr), oxygen (O), and nitrogen (N), the layer can be etched by a dry etching gas using a gas mixture of a chlorine-based gas and oxygen gas or using oxygen gas. In this case, the other of the first layer 41 and the second layer 42 is formed of a material resistant to the gas mixture or the oxygen gas. Examples of such resistant material include the HfAl material, the AlSi material, and a material further containing at least one of oxygen (O), nitrogen (N), carbon (C), and boron (B) in addition to the above-mentioned materials.

In this case, the other layer of the first layer 41 and the second layer 42 can be etched by a dry etching gas using an oxygen-free halogen-based gas (chlorine-based gas, fluorine-based gas, etc.). In this case, either the first layer 41 or the second layer 42 is resistant to the halogen-based gas mentioned above.

It is noted that the first layer 41 and the second layer 42 of the thin film 40 may not have etching selectivity with each other. In this case, it is preferable that the thin film 40 has an etching stopper layer between the first layer 41 and the second layer 42.

It is sufficient as long as a material of the etching stopper layer has etching selectivity with respect to the first layer 41 and the second layer 42. The material of the etching stopper layer is not particularly limited and may be selected, taking the etching selectivity into consideration, from various materials containing the above-mentioned elements recited as the material constituting the thin film 40.

### <Etching Mask Film 50>

The etching mask film 50 may be formed on the thin film 40 if needed. The etching mask film 50 may be a single layer or a stacked film formed by stacking a plurality of films. When the etching mask film 50 is the stacked film, each layer preferably has etching selectivity with respect to each of other layers formed above and below.

It is sufficient as long as a material of the etching mask film 50 has etching selectivity with respect to an uppermost layer of the thin film 40 (for example, the first layer 41 in the figure). The material of the etching mask film 50 is not particularly limited and may be, for example, a material containing at least one of Cr, Ta, and Si, and a material further containing at least one of O, N, C, and B in addition to the above-mentioned material. In particular, a Cr-containing material (Cr-based material) has high adhesion to the resist film and is therefore preferable. Similarly, a Ta-containing material (Ta-based material) is also preferable.

When the etching mask film 50 is a stacked film including two or more layers, a three-layer stacked structure is preferable and a four-layer stacked structure is more preferable. When the etching mask film 50 is a stacked film, it is preferable to combine a layer made of a material containing Cr and a layer made of a material containing Ta. Furthermore, when the etching mask film 50 is a stacked film, a layer closest to the thin film 40 is made of a material having a high etching rate (such as CrOCN), thereby improving pattern accuracy.

For example, when the etching mask film 50 comprises three layers, the etching mask film 50 may include an etching mask lower layer of a Cr-based material formed on the thin film 40, an etching mask interlayer of a Ta-based material formed on the etching mask lower layer, and an etching mask upper layer of a Cr-based material formed on the etching mask interlayer.

For example, when the etching mask film 50 comprises four layers, the etching mask film 50 may include a lowermost layer (etching mask lower layer) of a Cr-based material formed on the thin film 40, an etching mask interlayer of a Ta-based material formed on the etching mask lower layer, an etching mask upper layer of a Cr-based material formed on the etching mask interlayer, and an etching mask uppermost layer of a Ta-based material formed on the etching mask upper layer.

When the etching mask film 50 comprises three or four layers as mentioned above, the etching mask lower layer is composed of a material having a high etching rate (such as CrOCN) and has a small film thickness. Preferably, the etching mask upper layer is composed of a material having a low etching rate (such as CrOC) and has a film thickness greater than that of the etching mask lower layer. With this configuration, the etching mask upper layer can remain during etching of the etching mask lower layer so as to assure a sufficient film thickness of the etching mask film 50 required in subsequent etching of the first layer 41 and the second layer 42.

<Structure of Reflective Mask 1a>

The reflective mask 1a has the transfer pattern 40a formed by patterning the thin film 40. The reflective mask 1a may have a pattern region provided with the transfer pattern 40a and a non-pattern region without the transfer pattern 40a. The non-pattern region is provided as a peripheral region of the pattern region having the transfer pattern 40a. The non-pattern region may be, for example, a region covered with a film (binary film) having an absolute reflectance of 2.5% or less, which is not shown in the figure. The binary film may be separately formed between the etching mask film 50 and the thin film 40. When the etching mask film 50 has an absolute reflectance of 2.5% or less, the etching mask film 50 may be used as the binary film.

<Configuration of Transfer Pattern 40a in Reflective Mask 1a>

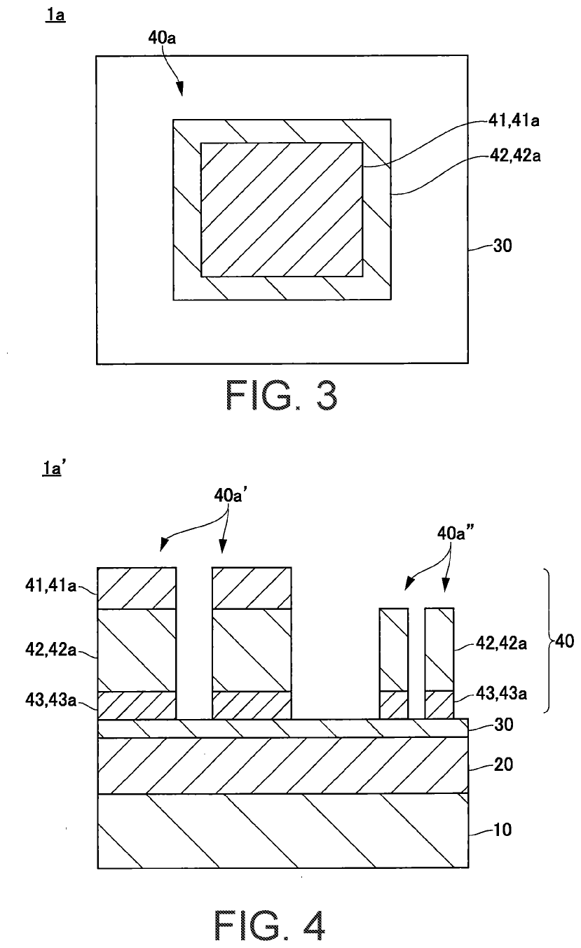

FIG. 3 is a plan view showing a configuration of the reflective mask 1a according to an embodiment of the present disclosure. The reflective mask 1a shown in FIGS. 2 and 3 has the transfer pattern 40a of an island shape formed by patterning the thin film 40. The transfer pattern 40a is formed by patterning the thin film 40 in which the lowermost layer 43, the second layer 42, and the first layer 41 are stacked on the substrate 10 in this order. The transfer pattern 40a is composed of a first layer pattern (second upper layer pattern) 41a obtained by patterning the first layer 41, a second layer pattern (lower layer pattern) 42a obtained by patterning the second layer 42, and a lowermost layer pattern 43a obtained by patterning the lowermost layer 43. FIGS. 2 and 3 show a configuration in which the first layer pattern 41a (first layer 41) is formed on the second layer pattern 42a (second layer 42) by way of example. Alternatively, the second layer pattern 42a may be formed on the first layer pattern 41a. In this case, the first layer pattern serves as a lower layer pattern and the second layer pattern serves as a second upper layer pattern. This also applies in the following.

In the transfer pattern 40a, a surface of an outer peripheral portion of the lower layer pattern 42a placed at a lower position is exposed over an entire circumference of the second upper layer pattern 41a as seen in a plan view. Therefore, in a planar shape of the transfer pattern 40a, the entire circumference of the second upper layer pattern 41a is surrounded by the lower layer pattern 42a. A cross-sectional shape of the transfer pattern 40a is a stepped shape in which the lower layer pattern 42a protrudes at a position one-step lower than the second upper layer pattern 41a. In the plan view of the transfer pattern 40a, an exposure width of the lower layer pattern 42a from the second upper layer pattern 41a may be 10 nm to 40 nm. The exposure width may be a different value depending on a position of the transfer pattern 40a according to an incident direction of the EUV light [H1] as the exposure light for the reflective mask 1a.

Thus, the reflective mask 1a has a configuration in which each of the first layer 41 and the second layer 42 is at least partially exposed in a plan view, at least a part of the second layer 42 is covered with the first layer 41 to form a stack region, and the second layer 42 is exposed at an outer periphery of the stacked region. The lowermost layer pattern 43a preferably has a planar shape same as that of the lower layer pattern 42a. When other layer is provided between the first layer 41 and the second layer 42, the other layer preferably has a planar shape same as that of the second upper layer pattern 41a placed thereon.

In the reflective mask 1a having the above-mentioned configuration, the lower layer pattern 42a having a high reflectance with respect to the EUV light [H1] is exposed at the outer periphery of the island-shaped transfer pattern 40a, that is, at a portion constituting a contour of the transfer pattern 40a in a plan view. This enables pattern exposure with a high phase shift effect for the reference reflected light [Rf0] from the multilayer reflective film 20. In addition, the second upper layer pattern 41a having a low reflectance with respect to the EUV light [H1] is exposed at a central portion of the island-shaped transfer pattern 40a. With this configuration, the amount of reflected light over the entirety of the transfer pattern 40a is suppressed and thus pattern exposure ensuring the exposure margin is enabled. As a result, pattern exposure with a large exposure margin and a high resolution can be performed without interfering with the phase shift effect in the reflective mask 1a of a phase shift type.

When the transfer pattern 40a is a line-and-space pattern, the outer peripheral portion of the lower layer pattern 42a may be exposed from a side peripheral portion of the second upper layer pattern 41a along a longitudinal direction of a line pattern in a plan view. The transfer pattern 40a may also be a hole pattern. In this case, in a plan view, the lower layer pattern 42a is formed so as to surround a hole region where the multilayer reflective film 20 (including the protective film 30) is exposed, and the second upper layer pattern 41a is formed so as to cover the lower layer pattern 42a while a surface of the peripheral portion of the lower layer pattern 42a is exposed by a predetermined width, the peripheral portion of the lower layer pattern 42a being in contact with the hole region.

The reflective mask blank 1 shown in FIG. 1 may have the thin film 40 in which the first layer 41 is stacked on the second layer 42 as described above. Thus, by stepwise patterning of the thin film 40, it is possible to obtain the reflective mask 1a illustrated in FIGS. 2 and 3, i.e., the reflective mask 1a having the transfer pattern 40a in which the contour is formed of the second layer 42 having a relatively high reflectance and the central portion is formed of the first layer 41 having a relatively low reflectance.

<Another Example of Reflective Mask 1a′>

FIG. 4 is a cross-sectional view showing a reflective mask 1a′ having another configuration according to the embodiment of the present disclosure. The reflective mask 1a′ shown in FIG. 4 has a first transfer pattern 40a′ and a second transfer pattern 40a″ formed by patterning the thin film 40 of the reflective mask blank 1 shown in FIG. 1.

In a plan view of the first transfer pattern 40a′, the lower layer pattern 42a is covered with the second upper layer pattern 41a and is not exposed. That is, the first transfer pattern 40a′ may have a configuration in which the second upper layer pattern 41a, the lower layer pattern 42a, and the lowermost layer pattern 43a are stacked in a substantially same planar shape. On the other hand, the second transfer pattern 40a″ has a configuration in which the lower layer pattern 42a and the lowermost layer pattern 43a are stacked in a substantially same shape. The second transfer pattern 40a″ does not include the first layer 41, and only the second layer 42 is exposed on a surface of the second transfer pattern 40a″ in plan view.

As a result, the reflective mask 1a′ has a configuration in which each of the first layer 41 and the second layer 42 is at least partially exposed in plan view.

In the reflective mask 1a′ having the above-mentioned configuration, pattern exposure with a high phase shift effect for the reference reflected light [Rf0] from the multilayer reflective film 20 (including the protective film 30) is enabled by the second transfer pattern 40a″ in which the lower layer pattern 42a having a high reflectance with respect to the EUV light [H1] is exposed. The second transfer pattern 40a″ is particularly useful when the second transfer pattern 40a″ has a so small size that the second transfer pattern 40a″ preferably has a relatively high reflectance (for example, more than 6%) in order to obtain a sufficient phase shift effect. On the other hand, the first transfer pattern 40a′ in which the second upper layer pattern 41a having a low reflectance with respect to the EUV light [H1] is exposed enables pattern exposure utilizing the phase shift effect while suppressing the amount of reflected light from the first transfer pattern 40a′ and ensuring the exposure margin. The first transfer pattern 40a′ is particularly useful when the first transfer pattern 40a′ has a size such that a sufficient phase shift effect is obtained, for example, at a relatively low reflectance (for example, about 6%). As a result, with one reflective mask 1a, it is possible to simultaneously obtain a high phase shift effect and a large exposure margin in conformity with the size of the pattern. Even when there are a region where a high reflectance is preferred and a region where a low reflectance is preferred depending on a type (shape) or a pitch of a pattern to be transferred, it is possible to perform pattern formation by exposure using only one reflective mask 1a.

The reflective mask blank 1 shown in FIG. 1 has a configuration in which the thin film 40 includes the first layer 41 and the second layer 42 described above, thereby making it possible to prepare the reflective mask 1a′ shown in FIG. 4. By using this reflective mask blank 1, it is possible to manufacture the reflective mask 1a′ capable of performing fine pattern transfer with a sufficient margin and high accuracy without complicating a process (mask manufacturing process) when manufacturing the phase shift mask.

The reflective mask 1a′ of the configuration shown in FIG. 4 is formed by using the reflective mask blank 1 described with reference to FIG. 1. However, a reflective mask equivalent thereto may be formed by using the reflective mask blank in which the first layer 41 and the second layer 42 are stacked in reverse order.

### <Method of Manufacturing Reflective Mask>

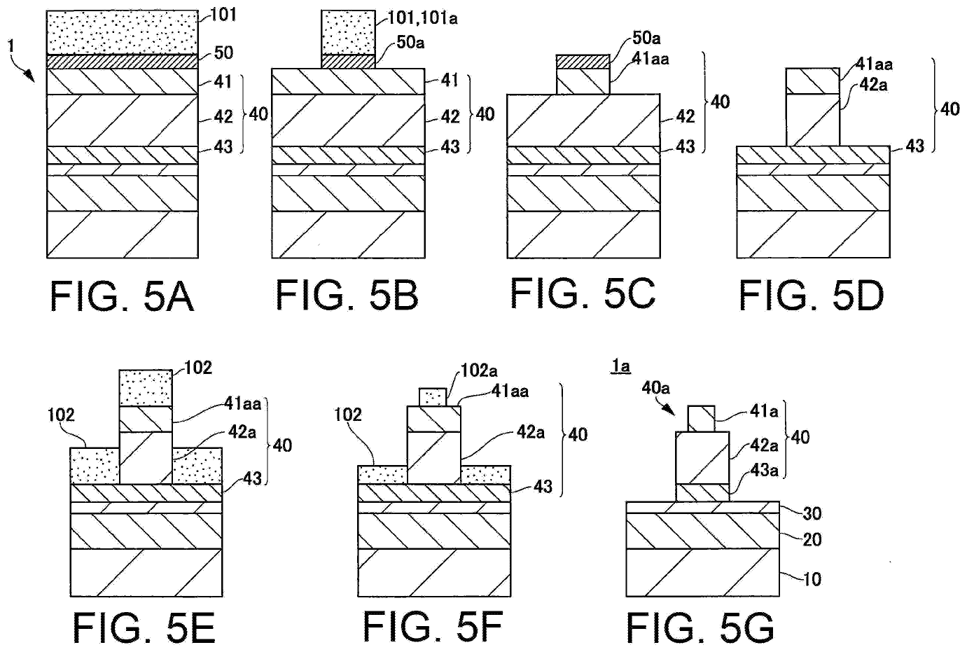

FIG. 5 is a manufacturing process diagram showing an example of a method of manufacturing a reflective mask according to the present disclosure, and is a view showing steps for manufacturing the reflective mask 1a shown in FIGS. 2 and 3 by using the reflective mask blank 1 shown in FIG. 1. The method of manufacturing the reflective mask will be described below with reference to FIG. 5.

First, as shown in FIG. 5A, a reflective mask blank 1 is prepared. The reflective mask blank 1 has been described using FIG. 1, and has the thin film 40 including the first layer 41 and the second layer 42. The thin film 40 is a stacked film in which one of the first layer 41 and the second layer 42 which is closer to the substrate 10 is a lower layer and the other is an upper layer. Herein, the second layer 42 is a lower layer and the first layer 41 is an upper layer by way of example.

The reflective mask blank 1 may have the etching mask film 50 formed on the thin film 40. It is noted that, when the reflective mask blank 1 does not have the etching mask film 50, the etching mask film 50 is formed on the thin film 40 as needed. Thereafter, a resist film 101 is formed on the etching mask film 50, for example, by spin coating. In some cases, the reflective mask blank 1 is provided with the resist film 101. In this case, the film forming step of the resist film 101 is not required.

Next, as shown in FIG. 5B, the resist film 101 is subjected to lithography to form a resist pattern 101a formed by patterning the resist film 101. In the lithography, for example, exposure by electron beam writing, development, and rinsing are performed.

Thereafter, the etching mask film 50 is etched using the resist pattern 101a as a mask to form an etching mask pattern 50a. An etching gas used in etching the etching mask film 50 may be appropriately selected depending on the material of the etching mask film 50. For example, when the etching mask film 50 is made of a Cr-based material, chlorine gas (Cl₂) and oxygen gas (O₂) can be used as the etching gas. On the other hand, when the etching mask film 50 is made of, for example, a TaO material as a Ta-based material, the etching mask film 50 can be etched using a fluorine-based gas. Although not shown in the figure, when the etching mask film 50 is a stacked film including a plurality of layers made of different materials from each other, the etching gas may be changed depending on the material of each layer to etch the etching mask film 50.

Next, as shown in FIG. 5C, the first layer 41 of the thin film 40 is etched using the etching mask pattern 50a (and the resist pattern 101a) as a mask to form a first upper layer pattern 41aa.

At this time, the etching gas for the first layer 41 may be appropriately selected depending on the material of the first layer 41. For example, when the first layer 41 is made of a HfAl material or an AlSi material, a gas mixture of chlorine gas (Cl₂) and boron trichloride (BCl₃) may be used as the etching gas. In this etching, the resist pattern 101a is also removed. The HfAl material and the AlSi material may further contain at least one of oxygen (O), nitrogen (N), carbon (C), and boron (B).

Thereafter, as shown in FIG. 5D, the second layer 42 of the thin film 40 is etched using the etching mask pattern 50a and the first upper layer pattern 41aa as a mask to form the lower layer pattern 42a. The lower layer pattern 42a is formed by patterning the second layer 42 as the lower layer of the thin film 40.

At this time, the etching gas for the second layer 42 may be appropriately selected depending on the material of the second layer 42. For example, when the second layer 42 is made of a RuN material or a RuCr material, a gas mixture of chlorine gas (Cl₂) and oxygen gas (O₂) may be used as the etching gas. When the second layer 42 is made of a RuPt material or a RuTa material, for example, a fluorine-based gas may be used as an etching gas. The RuCr material, the RuN material, the RuPt material, and the RuTa material may further contain at least one of oxygen (O), nitrogen (N), carbon (C), and boron (B).

Next, as shown in FIG. 5E, a resist film 102 is formed by coating above the substrate 10 provided with the first upper layer pattern 41aa.

Thereafter, as shown in FIG. 5F, the resist film 102 is subjected to lithography to form a resist pattern 102a by patterning the resist film 102. Herein, the resist pattern 102a slightly smaller in planar shape than the lower layer pattern 42a is formed. In the lithography, for example, exposure by electron beam writing, development, and rinsing are performed. In the lithography, depending on the material of the lowermost layer 43, the resist film 102 may remain on the lowermost layer 43 as illustrated in the figure or electron beam writing may be performed so as to remove the resist film 102 on the lowermost layer 43.

Thereafter, the first upper layer pattern 41aa is further etched using the resist pattern 102a as a mask to form the second upper layer pattern 41a slightly smaller in planar shape than the lower layer pattern 42a.

In the etching of the first upper layer pattern 41aa, the same etching gas as that in a step of FIG. 5C may be used. Also, in this etching, the resist pattern 102a is also reduced in thickness.

Subsequently, as shown in FIG. 5G, the resist pattern 102a (and the resist film 102) remaining above the substrate 10 is removed. Then, by etching the lowermost layer 43 using the lower layer pattern 42a as a mask, the lowermost layer 43 is patterned to form the lowermost layer pattern 43a same in planar shape as the lower layer pattern 42a. At this time, an etching gas may be appropriately selected depending on the material of the lowermost layer 43. For example, when the lowermost layer 43 is made of TaON, a fluorine-based gas may be used as the etching gas.

Thus, the reflective mask 1a having the transfer pattern 40a described with reference to FIGS. 2 and 3 is obtained.

The reflective mask 1a′ described with reference to FIG. 4 is also formed partially via the steps same as those shown in FIGS. 5A through 5E. In steps subsequent to FIG. 5E, the resist pattern 102a is formed so that the first upper layer pattern 41aa is exposed in a region corresponding to the second transfer pattern 40a″. After etching the exposed first upper layer pattern 41aa, the resist pattern 102a is removed and the lowermost layer 43 is etched using the lower layer pattern 42a as a mask. Thus, the first transfer pattern 40a′ and the second transfer pattern 40a″ can be formed. It is noted that, in this reflective mask 1a′, the first layer 41 and the second layer 42 may be stacked in reverse order. Therefore, the reflective mask blank prepared in FIG. 5A may have the thin film 40 with the first layer 41 as a lower layer and the second layer 42 as an upper layer

### EXAMPLES

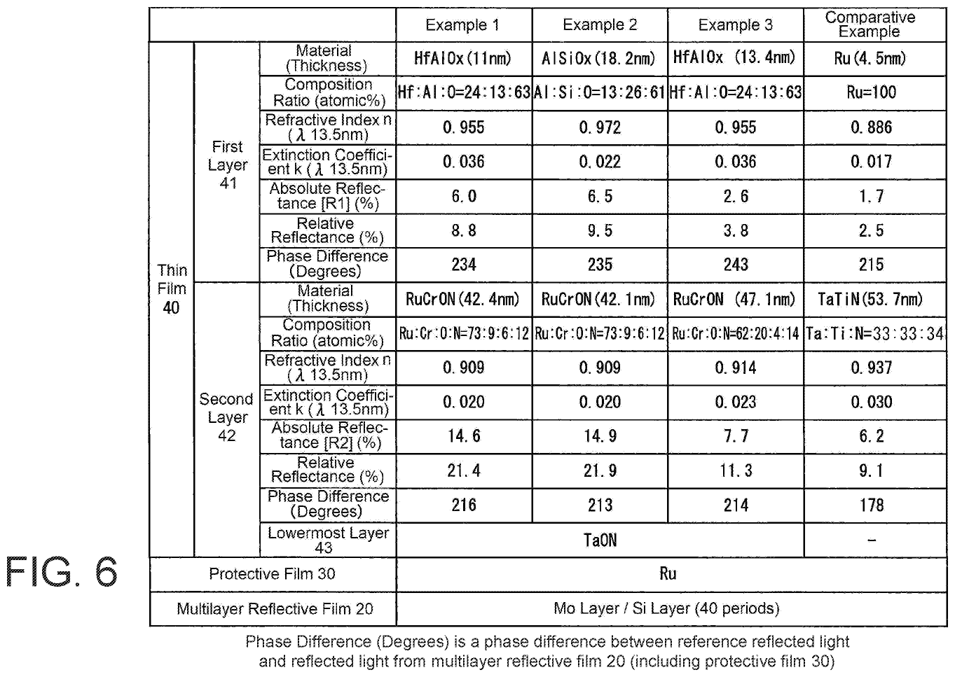

Next, Examples according to the present disclosure and Comparative Example will be described. FIG. 6 is a view showing compositions and physical properties of the thin films of Examples and Comparative Example. Hereinafter, Examples and Comparative Example will be described with reference to FIGS. 1 and 6.

In Examples 1-3 and Comparative Example, respective layers of the reflective mask blank 1 of a stacked structure shown in FIG. 1 were formed of materials shown in FIG. 6. In Examples and Comparative Example, the first layer 41 is an upper layer and the second layer 42 is a lower layer by way of example, although the present disclosure is not limited thereto. In the first layer 41 and the second layer 42 constituting the thin film 40, a reflectance with respect to the EUV light [H1] and a phase difference between each of the first reflected light [Rf1] and the second reflected light [Rf2] and the reference reflected light [Rf0] from the multilayer reflective film 20 via the protective film 30 are adjusted by materials, composition ratios of the materials, and film thicknesses.

### Example 1

An SiO₂—TiO₂-based glass substrate (6-inch square, thickness of 6.35 mm) was prepared. End faces of the substrate were subjected to chamfering and grinding, and further subjected to rough polishing with a polishing liquid containing cerium oxide abrasive grains. The substrate after the above-mentioned processes was set to a carrier of a double-sided polishing device, and subjected to precision polishing under a predetermined polishing condition, using an alkaline aqueous solution containing colloidal silica abrasive grains as a polishing liquid. After completion of the precision polishing, the substrate was cleaned. A surface roughness of a main surface of the glass substrate thus obtained was 0.10 nm or less in root mean square roughness (Rq). A flatness of the main surface of the substrate thus obtained was 30 nm or less in a measurement region of 132 mm×132 mm.

On a back surface of the substrate, a backside conductive film of CrN was formed by magnetron sputtering under the following conditions.

Condition: Cr target, Ar+N₂ gas atmosphere, film composition (Cr: 90 atomic %, N: 10 atomic %), film thickness of 20 nm

On the main surface of the substrate opposite to the back surface, the multilayer reflective film was formed by periodically stacking Mo films and Si films. Specifically, the Mo films and the Si films were alternately stacked on the substrate by ion beam sputtering using a Mo target and a Si target in an Ar gas atmosphere. Each of the Mo films has a thickness of 2.8 nm. Each of the Si films has a thickness of 4.2 nm. One period (unit) of the Mo/Si films has a thickness of 7.0 nm. The Mo/Si films were stacked in 40 periods (units). Finally, the Si film was formed with a film thickness of 4.0 nm to form the multilayer reflective film.

A protective film containing Ru was formed on the multilayer reflective film. Specifically, the protective film made of a Ru film was formed on the multilayer reflective film by DC sputtering using a Ru target in an Ar gas atmosphere. The protective film had a thickness of 3.5 nm.

Next, a TaON film was formed as the lowermost layer on the protective film by DC sputtering. The TaON film was deposited using a Ta target in an atmosphere containing Ar gas, oxygen gas, and nitrogen gas.

By DC sputtering, a second layer (lower layer) made of a RuCrON film was formed on the lowermost layer made of the TaON film. The RuCrON film was deposited using a RuCr target in an atmosphere containing Ar gas, oxygen gas, and nitrogen gas.

By RF sputtering, a HfAlO film was formed as a first layer (upper layer) on the second layer made of the RuCrON film. The HfAlO film was deposited in an argon (Ar) gas atmosphere using an Al₂O₃ target and a HfO₂ target. Thus, the reflective mask blank of Example 1 was obtained.

### Example 2

In Example 2, the first layer (upper layer) and the film thickness of the second layer (lower layer) made of the RuCrON film are different from those in Example 1.

In the same manner as that of Example 1, a backside conductive film, a multilayer reflective film, a protective film, and a RuCrON film were deposited on the substrate. It is noted that the film thickness of the RuCrON film was changed from that of Example 1.

By RF sputtering, an AlSiO film was formed as the first layer (upper layer) on the lower layer made of the RuCrON film. The AlSiO film was deposited in an argon (Ar) gas atmosphere using an Al₂O₃ target and a SiO₂ target. Thus, the reflective mask blank of Example 2 was obtained.

### Example 3

In Example 3, a composition ratio of the second layer (lower layer) made of the RuCrON film and the film thickness of the first layer (upper layer) were changed from those in Example 1.

In the same manner as that of Example 1, a backside conductive film, a multilayer reflective film, and a protective film were formed on a substrate. Furthermore, a flow rate ratio of the sputtering gas during deposition of the RuCrON film in Example 1 was adjusted and a RuCrON film of Example 3 was deposited as a lower layer. The film thickness of the RuCrON film was also changed from that in Example 1.

In the same manner as that of Example 1, a HfAlO film was formed as a first layer (upper layer) on the lower layer made of the RuCrON film. It is noted that the film thickness of the HfAlO film was changed from that in Example 1. Thus, a reflective mask blank of Example 3 was obtained.

### Comparative Example

In the comparative example, a thin film is different from that in Example 1. By DC magnetron sputtering, a second layer (lower layer) made of a TaTiN film was formed on a protective film. The TaTiN film was deposited in an atmosphere of Ar gas and N₂ gas using a TaTi target.

On the lower layer made of the TaTiN film, a first layer (upper layer) was formed with a material containing Ru. Specifically, a Ru film was deposited by DC sputtering using a Ru target in an Ar gas atmosphere. Thus, a reflective mask blank 1 in Comparative Example was obtained.

Using the reflective mask blank 1 in each of Examples 1 to 3 and Comparative Example, the reflective mask 1a having the island-shaped transfer pattern 40a described with reference to FIGS. 2 and 3 was prepared via the procedure described with reference to FIG. 5. The HfAlO film and the AlSiO film were etched using BCl₃ gas and Cl₂ gas. The Ru film and the RuCrON film were etched using Cl₂ gas and O₂ gas. The TaTiN film was etched using Cl₂ gas. The TaON film was etched using fluorine gas. The transfer pattern 40a had a rectangular shape of 200 nm×200 nm square in plan view of the lower layer pattern 42a. In plan view of the transfer pattern 40a, an exposed width of the lower layer pattern 42a was 20 nm.

In the reflective mask blank 1 of Examples 1 to 3, the absolute reflectance [R1] of the first layer 41 constituting the thin film 40 with respect to the EUV light [H1] was greater than 2.5%. The absolute reflectance [R2] of the second layer 42 constituting the thin film 40 with respect to the EUV light [H1] was higher than the absolute reflectance [R1] of the first layer 41.

With respect to the reference reflected light [Rf0] from the multilayer reflective film 20 (including the protective film 30) irradiated with the EUV light [H1], the phase difference of each of the first reflected light [Rf1] from the first layer 41 and the second reflected light [Rf2] from the second layer 42 was 150 degrees or more. The phase difference between the reflected light from the first layer 41 and the reflected light from the second layer 42 was 30 degrees or less.

In contrast, in the reflective mask blank 1 of Comparative Example, the first layer 41 constituting the thin film 40 had the absolute reflectance [R1] of 1.7% with respect to the EUV light [H1], which was lower than 2.5% and beyond the scope of the embodiment of the present disclosure.

Further, in the reflective mask blank 1 of Comparative Example, the phase difference between the first reflected light [Rf1] from the first layer 41 and the second reflected light [Rf2] from the second layer 42 was 37 degrees and beyond a preferable range of the embodiment of the present disclosure.

Simulation of the EUV exposure was carried out using each of the prepared reflective masks 1a. As a result, it was confirmed that a transferred optical image having a high contrast could be obtained in the EUV exposure using each of the reflective masks 1a in Examples 1 to 3. In a region where the first layer 41 and the second layer 42 were stacked, the absolute reflectance was relatively low. It has been found that, when pattern transfer was performed using the reflective mask 1a according to Examples 1 to 3, it is possible to sufficiently reduce the risk that a resist on a transfer-target (semiconductor) substrate reacts to light in a region where the resist should not react to the light. Thus, it has been found that the reflective mask 1a according to Examples 1 to 3 can achieve both a high phase shift effect and a large exposure margin. As a result, it has been found that, by applying the EUV exposure using the reflective mask 1a of the present disclosure to manufacture of a semiconductor device, it is possible to form a fine circuit pattern with high accuracy and to achieve higher functionality and higher integration of the semiconductor device.

On the other hand, in the reflective mask 1a of Comparative Example, the absolute reflectance was as low as 1.7% in the region where the first layer 41 and the second layer 42 are stacked, and a sufficient phase shift effect was not obtained. Therefore, in the EUV exposure using the reflective mask 1a of Comparative Example, the contrast of a resultant transferred optical image was insufficient. Thus, it has been found that, when the EUV exposure using the reflective mask 1a beyond the scope of the present disclosure, it is difficult to form a fine circuit pattern with high accuracy even when EUV exposure using a reflective mask 1a outside the scope of the present disclosure is applied to the manufacturing of a semiconductor device. Also, in the comparative example, the phase difference between the first reflected light [Rf1] from the first layer 41 and the second reflected light [Rf2] from the second layer 42 was greater than those in Examples 1 to 3. Therefore, due to the interference between the first reflected light [Rf1] and the second reflected light [Rf2], the amount of reflected light (intensity) decreases in the vicinity of the edge of the transfer pattern 40a, so that the phase shift effect was not sufficiently obtained. It was supposed that this was also a factor for difficulty in formation of a fine circuit pattern with high accuracy.

What is claimed is:

1. A reflective mask blank comprising:
a substrate;
a multilayer reflective film formed on the substrate; and
a thin film formed on the multilayer reflective film;
wherein the thin film includes a first layer and a second layer;
wherein the first layer has a reflectance greater than 2.5% with respect to EUV light; and
wherein the second layer has a reflectance greater than the reflectance of the first layer with respect to the EUV light.

2. The reflective mask blank according to claim 1,
wherein a phase difference between first reflected light reflected from the first layer irradiated with the EUV light and second reflected light reflected from the second layer irradiated with the EUV light is 30 degrees or less.

3. The reflective mask blank according to claim 1,
wherein light reflected from the multilayer reflective film irradiated with the EUV light is defined as reference reflected light;
wherein a phase difference between the reference reflected light and first reflected light reflected from the first layer irradiated with the EUV light is 150 degrees or more;
wherein a phase difference between the reference reflected light and second reflected light reflected from the second layer irradiated with the EUV light is 150 degrees or more.

4. The reflective mask blank according to claim 1,
wherein the thin film has a lowermost layer formed closest to the substrate.

5. The reflective mask blank according to claim 1,
wherein the first layer or the second layer comprises at least one of ruthenium, tantalum, and chromium.

6. The reflective mask blank according to claim 1,
wherein the first layer is formed on the second layer.

7. The reflective mask blank according to claim 6,
wherein the second layer comprises at least one of ruthenium and chromium.

8. The reflective mask blank according to claim 1,
wherein an etching mask film that comprises two or more layers is formed on the thin film.

9. A method of manufacturing a reflective mask using the reflective mask blank comprising:
forming an etching mask pattern by etching the etching mask film;
forming a first upper layer pattern by etching the upper layer with the etching mask pattern used as a mask;
forming a lower layer pattern by etching the lower layer with the first upper layer pattern used as a mask; and
forming a transfer pattern by etching the first upper layer pattern to form a second upper layer pattern,
wherein one of the first layer and the second layer which is formed closer to the substrate is defined as a lower layer and the other is defined as an upper layer, and
wherein the first layer has a reflectance greater than 2.5% with respect to EUV light, and
wherein the second layer has a reflectance greater than the reflectance of the first layer with respect to the EUV light.

10. The method of manufacturing a reflective mask according to claim 9,
wherein the thin film has a lowermost layer formed under the lower layer;
wherein the method further comprises removing the lowermost layer in a region where the lower layer has been etched.

11. A reflective mask comprising:
a substrate;
a multilayer reflective film formed on the substrate; and
a thin film formed on the multilayer reflective film and provided with a transfer pattern;
wherein the thin film includes a first layer and a second layer;
wherein the first layer has a reflectance greater than 2.5% with respect to EUV light;
wherein the second layer has a reflectance greater than the reflectance of the first layer with respect to the EUV light.

12. The reflective mask according to claim 11,
wherein a phase difference between first reflected light reflected from the first layer irradiated with the EUV light and second reflected light reflected from the second layer irradiated with the EUV light is 30 degrees or less.

13. The reflective mask according to claim 11,
wherein light reflected from the multilayer reflective film irradiated with the EUV light is defined as reference reflected light;
wherein a phase difference between the reference reflected light and first reflected light reflected from the first layer irradiated with the EUV light is 150 degrees or more;
wherein a phase difference between the reference reflected light and second reflected light reflected from the second layer irradiated with the EUV light is 150 degrees or more.

14. The reflective mask according to claim 11,
wherein the thin film has a lowermost layer formed closest to the substrate.

15. The reflective mask according to claim 11,
wherein the first layer or the second layer comprises at least one of ruthenium, tantalum, and chromium.

16. The reflective mask according to claim 11,
wherein the first layer is formed on the second layer.

17. The reflective mask according to claim 16,
wherein the second layer comprises at least one of ruthenium and chromium.

18. The reflective mask according to claim 11, wherein each of the first layer and the second layer is at least partially exposed in plan view.

19. The reflective mask according to claim 11,
wherein the reflective mask has a stacked region in which at least a part of the second layer is covered with the first layer;
wherein the second layer is exposed at an outer periphery of the stacked region.

20. The method according to claim 9,
wherein a phase difference between first reflected light reflected from the first layer irradiated with the EUV light and second reflected light reflected from the second layer irradiated with the EUV light is 30 degrees or less.

21. The method according to claim 9,
wherein light reflected from the multilayer reflective film irradiated with the EUV light is defined as reference reflected light;
wherein a phase difference between the reference reflected light and first reflected light reflected from the first layer irradiated with the EUV light is 150 degrees or more;
wherein a phase difference between the reference reflected light and second reflected light reflected from the second layer irradiated with the EUV light is 150 degrees or more.
